(19) United States
(12) Patent Application Publication
(10) Pub. No.: US 2011/0273190 A1
(43) Pub. Date: Nov. 10, 2011

(54) Sensing Apparatus and Associated Methods

(75) Inventor: Steve Gerber, Austin, TX (US)

(73) Assignee: Silicon Laboratories Inc.

(21) Appl. No.: 12/982,870

(22) Filed: Dec. 30, 2010

Related U.S. Application Data
(63) Continuation of application No. 12/775,471, filed on May 6, 2010.

(51) Int. Cl. G01R 27/26

(52) U.S. Cl. 324/658

(57) ABSTRACT

An apparatus includes an integrated circuit (IC) configured to sense capacitance, and two or more capacitive elements coupled to the IC. The capacitive elements each have a first section, and one capacitive element has a second section. The first sections of the capacitive elements have the same or substantially the same lengths, shapes, and/or capacitance values.

### TECHNICAL FIELD

The disclosed concepts relate generally to electronic circuitry and related techniques. More particularly, the disclosed concepts relate to apparatus for sensing capacitance, and associated methods.

### BACKGROUND

Electronic circuitry often uses various interface circuitries such as capacitive sensors or sensor arrays that enable the user to interact with or receive information from an electronic circuit. The sensing circuitry may provide a way of implementing desired functionality by using, for example, dedicated sensing circuitry. The sensing circuitry may detect the activation of various capacitive elements, for example, capacitive switches within a capacitive sensor array enabling a user to input particular information into a circuit.

A capacitive sensor or sensor array should have the ability to detect differences in the capacitance value of a capacitive element or switch responsive to changes in the operating environment of the circuit, for example, the placement of a user's finger upon the capacitive switch. In addition to detecting the placement of a finger upon a capacitive switch and the associated change in capacitance caused by the finger, the sensing circuitry should be resistant to external interferences within the capacitive sensor array.

### SUMMARY

One aspect of the disclosed concepts relates to apparatus for sensing capacitance. In one exemplary embodiment, an apparatus includes an integrated circuit (IC), and first and second capacitive elements coupled to the IC. Each of the first and second capacitive elements has a first section (e.g., a length of conductor). The second capacitive element has a second section (e.g., a length of conductor, formed into a desired shape). The first sections of the first and second capacitive elements have substantially the same lengths.

In another exemplary embodiment, an apparatus for remote sensing of capacitance includes a capacitance sensing circuit. The apparatus further includes first and second capacitive elements remotely coupled to the capacitance sensing circuit. The first capacitive element has a first conductive segment. The second capacitive element has both a first conductive segment that is of substantially equal length to the first conductive segment of the first capacitive element, and a second conductive segment that extends beyond the first conductive segment of the second capacitive element.

Another aspect of the disclosed concepts relates to methods of sensing capacitance. In one exemplary embodiment, a method of sensing capacitance includes sensing capacitance via a first capacitive element that has a first section, and sensing capacitance via a second capacitive element that has first and second sections. The method further includes removing sensed capacitance associated with the first sections of first and second capacitive elements.

### BRIEF DESCRIPTION OF THE DRAWINGS

The appended drawings illustrate only exemplary embodiments and therefore should not be considered as limiting its scope. Persons of ordinary skill in the art who have the benefit of this disclosure appreciate that the disclosed concepts lend themselves to other equally effective embodiments. In the drawings, the same numeral designators used in more than one drawing denote the same, similar, or equivalent functionality, components, or blocks.

FIG. 1 is an upper level block diagram of an integrated circuit with capacitive sensing capabilities;

FIG. 2a shows a simplified functional block diagram of a capacitive touch sense circuitry.

FIG. 2b illustrates a simplified block diagram of an analog front end circuitry.

FIG. 3 depicts a timing diagram illustrating the operation of the circuitry of FIG. 2b.

FIG. 4 shows a simplified flow chart for the SAR algorithm for detecting the value of a capacitor on an external pin or conductor.

FIG. 5 illustrates a conventional capacitive sensor circuit for a consumer-electronics device.

FIG. 6 shows a simplified block diagram of remote capacitive sensing apparatus according to an exemplary embodiment.

FIG. 7 depicts a simplified block diagram of a capacitive sensor circuit for a consumer-electronics device according to an exemplary embodiment.

FIG. 8 illustrates a simplified block diagram of a capacitive sensing apparatus, including a common-mode wire, according to an exemplary embodiment.

FIG. 9 shows a simplified block diagram of a capacitive sensing apparatus, used in a cook-top application, according to an exemplary embodiment.

FIG. 10 depicts a simplified block diagram of a capacitive sensing apparatus according to an exemplary embodiment for use in test or measurement applications.

FIG. 11 illustrates a simplified block diagram of a charger according to an exemplary embodiment.

### DETAILED DESCRIPTION

The disclosed concepts relate generally to sensing apparatus and associated methods, for example, sensing capacitance. Broadly stated, apparatus and associated methods according to the disclosed concepts allow remote sensing or measuring of capacitance. As described in detail below, in exemplary embodiments, the sensing of capacitance may allow the determination of whether a specified event or condition exists. Apparatus or methods according to exemplary embodiments may then take specified or pre-determined steps or actions, as desired.

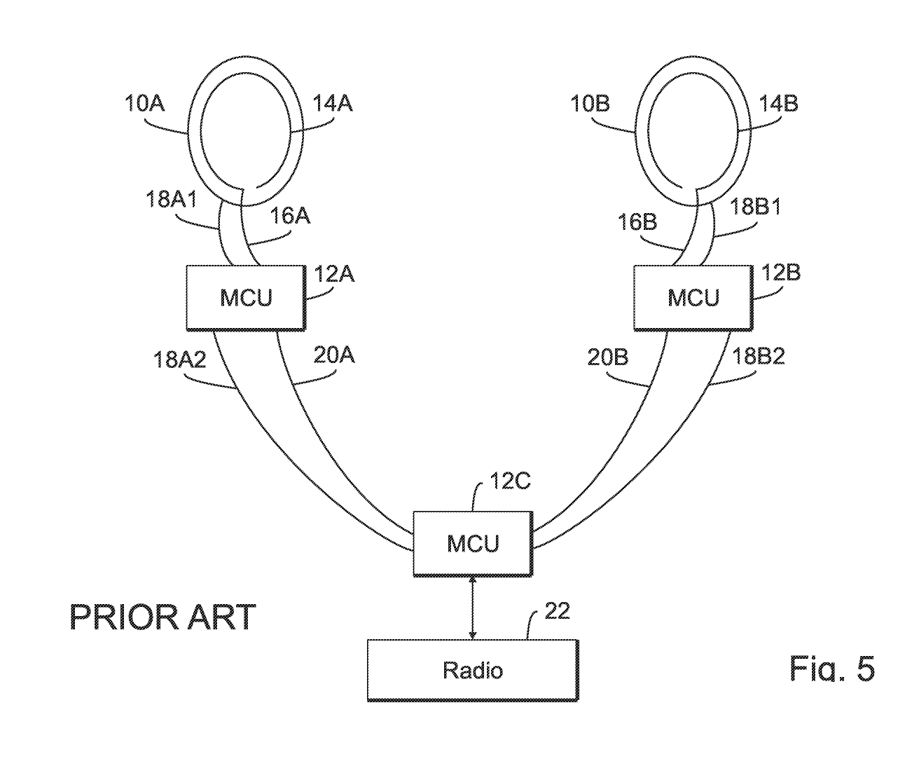

Modern electronic devices, for example, consumer electronics devices, sometimes use capacitive sensing circuitry. As an example, consider the apparatus in FIG. 5, which includes “ear buds” or earphones 10A-10B for a consumer-electronic device. Earphones 10A-10B provide stereo sound or music to the user of the device.

The apparatus includes several controllers, for example, microcontrollers or MCUs, labeled 12A-12C. MCUs 12A-12B couple to capacitive elements 14A-14B via lines 16A-16B. MCUs 12A-12B can sense the capacitance of capacitive elements 14A-14B.

MCUs 12A-12B also couple to MCU 12C via lines 20A-20B, respectively. By using lines 20A-20B, MCUs 12A-12B may communicate data with MCU 12C.

MCUs 12A-12B receive audio signals from radio 22 via MCU 12C. MCUs 12A-12B provide the audio signals to earphones 10A-10B via lines 18A1-18B1, respectively.

Conventional apparatus for capacitive sensing, for example, as shown in FIG. 5, uses sensing elements located relatively close to the sensing device (typically to minimize the total capacitance to ground or to minimize the length of the connection that may be sensitive to unintended conductive objects). For instance, in the circuit shown in FIG. 5, lines 16A-16B might have a length of about 2 inches. In comparison, lines 18A2-18B2 (or lines 20A-20B) might have lengths of about 10 inches. As a result, MCUs 12A-12B reside relatively close to the sensing region of interest (near elements 14A-14B). Furthermore, MCU 12C resides relatively close to MCUs 12A-12B. Note that additional power conductors (not shown explicitly) run from radio 22 (or another source) to MCU 12C, and from MCU 12C to MCUs 12A-12B.

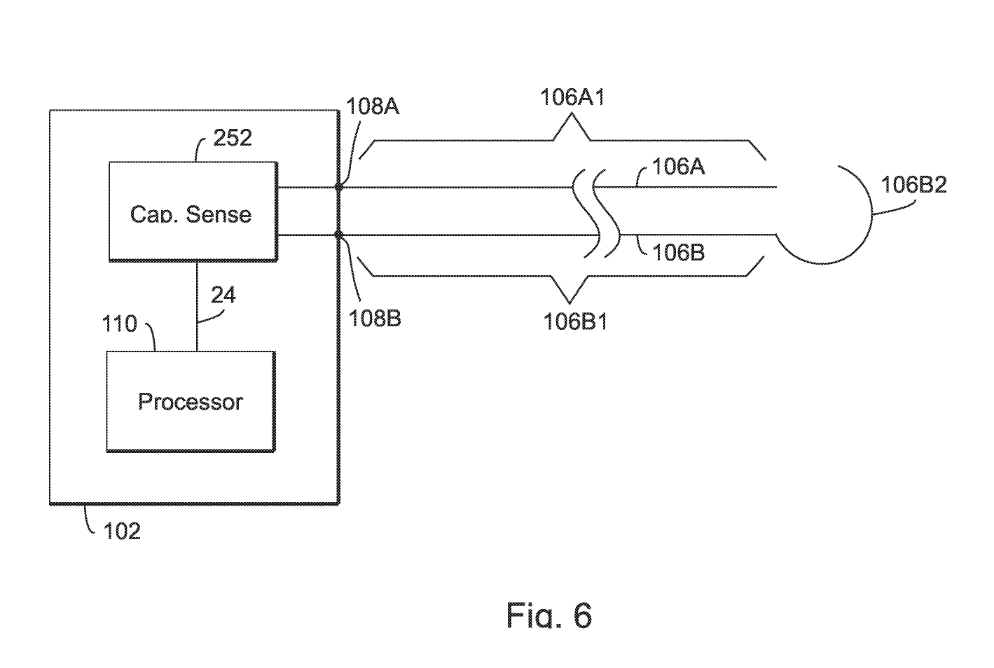

As noted above, exemplary embodiments of the disclosed concepts allow remote sensing of capacitance, for example, capacitive arrays or one or more capacitive elements. FIG. 6 shows a simplified block diagram of remote capacitive sensing apparatus according to an exemplary embodiment.

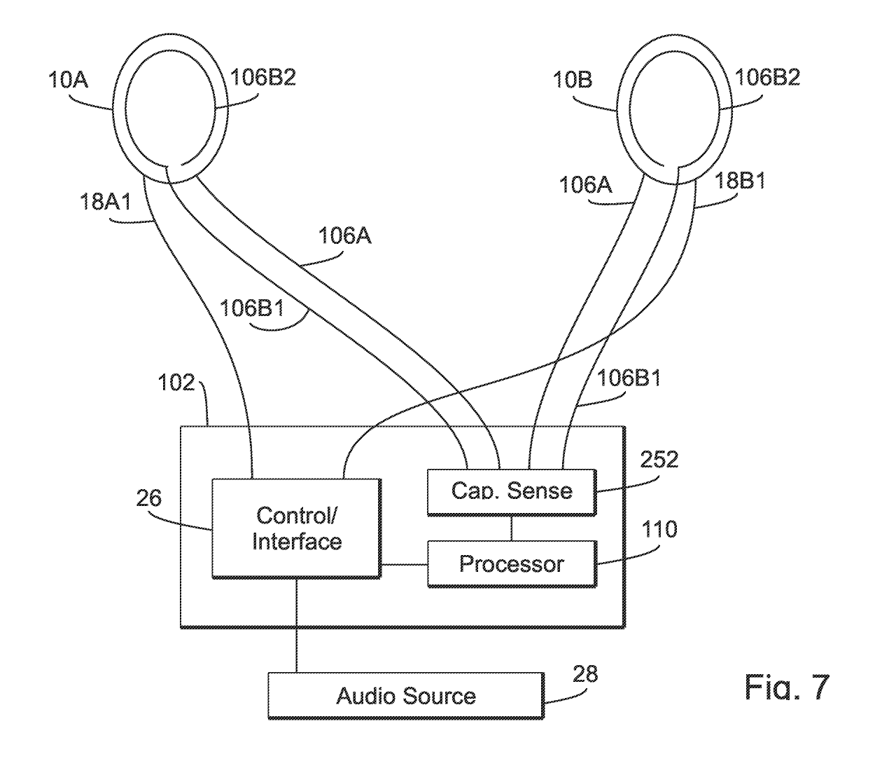

The apparatus in FIG. 6 includes an integrated circuit (IC) 102, coupled to capacitive element 106A and capacitive element 106B via pins or connectors 108A-108B. Note that, rather than using an IC, one may use other arrangements, for example, mufti-chip modules (MCM) or the like, as desired, and as persons of ordinary skill in the art who have the benefit of the description of the disclosed concepts understand. Furthermore, note that in the apparatus shown in FIG. 6 (and generally in other embodiments according to the disclosed concepts, as shown, for example, in FIGS. 7-11), one may use more than two capacitive elements, as desired, and as persons of ordinary skill in the art who have the benefit of the description of the disclosed concepts understand.

In the embodiment shown, IC 102 includes capacitive sense block or circuit 252, and processor 110. Capacitive sense block 252 couples to capacitive elements 106A-106B via pins 108A-108B, respectively. Capacitive sense block 252 can sense or measure the capacitance of capacitive element 106A and/or capacitive element 106B.

Processor 110 couples to capacitive sense block 252 via a link or bus 24. One may implement processor 110 in a wide variety of ways, as persons of ordinary skill in the art who have the benefit of the description of the disclosed concepts understand. For example, one may implement processor 110 as a general logic circuit, a finite-state machine, an MCU, programmed controller, etc., as desired.

Through link 24, processor 110 can communicate data, status, and/or control signals to or from capacitive sense block 252. As described below in detail, processor 110, operating in conjunction with capacitive sense block 252, can sense or measure the capacitance of external capacitors, such as capacitive elements 106A-106B. Depending on the results of the sensing or measuring operation(s), IC 102 (or processor 110) can cause further actions or changes in an electronic circuitry in which IC 102 resides.

Capacitive element 106A has a section, segment, or length of conductor 106A1. Similarly, capacitive element 106B has a section, segment, or length of conductor 106B1. Sections 106A1 and 106B1 include the same or substantially the same lengths of conductor, shapes, and/or capacitance values (e.g., lengths or capacitance values of within 1% or 5% or 10% in exemplary embodiments, shapes that overlap, for example, 90% or 95% or 99%). Note that sections 106A1 and 106B1 may have a wide variety of topological shapes, as desired, and as persons of ordinary skill in the art who have the benefit of the description of the disclosed concepts understand. Some examples include lines, curves, coils or loops (having shapes having a desired or specified cross-section).

In addition, capacitive element 106B includes a segment, section, or length of conductor 106B2. Section 106B2 extends beyond section 106B1 of capacitive element 106B. Similarly, section 106B2 extends beyond section 106A1 of capacitive element 106A.

Put another way, capacitive elements 106A-106B have a common (or substantially common) section, i.e., section 106A1 and section 106B1, respectively. Capacitive element 106B, however, extends beyond the common section, and has an extended or additional section 106B2.

In exemplary embodiments, section 106B2 of capacitive element 106B may have a variety of shapes, forms, and/or lengths, as desired. In the embodiment shown in FIG. 6, section 106B2 has an annular or ring shape. Other examples include a straight section, a curved section, a rectangular or square section, a loop, a polygon, and the like, as persons of ordinary skill in the art who have the benefit of the description of the disclosed concepts understand. Generally, the shape, geometry, and length of section 106B2 depends on the intended or desired application for the remote sensing apparatus.

The remote capacitive sensing apparatus operates by sensing or measuring the capacitance of one of capacitive elements 106A-106B. The apparatus then senses or measures the capacitance of the other capacitive element, and compares the two capacitance values. Depending on the relative capacitance values, the capacitive sense block 252, or more generally IC 102, can sense the presence of one or more conditions or events. Processor 110, or more generally IC 102, may take one or more actions in response to the condition(s) or event(s).

The capacitive sensing apparatus shown in FIG. 6 ignores or removes the effect of capacitance that is common to capacitive elements 106A-106B, i.e., the capacitance sensed or measured via sections 106A1 and 106B1 of capacitive elements 106A-106B. Put another way, the capacitive sensing apparatus ignores the changes in capacitance (or the measured or sensed capacitance) in the common sections (i.e., section 106A1 and 106B1) of capacitive elements 106A and 106B. By doing so, the capacitive sensing apparatus can respond to changes in capacitance (or the measured or sensed capacitance) in the extended section of capacitive element 106B, i.e., section 106B2.

Change in the capacitance of extended section 106B2 of capacitive element 106B may occur because of a variety of reasons, as persons of ordinary skill in the art who have the benefit of the description of the disclosed concepts understand. Examples include proximity to a human or a part or limb of a human (e.g., a finger or hand), a conductor, or other entity or element that causes a change in capacitance.

By ignoring (or removing the effect of) common-mode capacitance, the capacitive sensing apparatus of FIG. 6 can provide remote capacitive sensing capability. Thus, the capacitive sensing apparatus can function even with relatively or substantially long sections 106A1 and 106B1 of capacitive elements 106A-106B. In other words, by determining the changes in the capacitance of section 106B2 of capacitive element 106B2 and ignoring the common-mode capacitance, the capacitive sensing apparatus can allow relatively long or substantially long distances (e.g., distances over 1 foot, or 2 feet, or 3 feet (or more, depending on the application and implementation) in exemplary embodiments) between IC 102 and section 106B2.

FIG. 7 shows a simplified block diagram of a capacitive sensor circuit for a consumer-electronics device according to an exemplary embodiment. More specifically, the apparatus in FIG. 7 includes “ear buds” or headphones or earphones (generally, audio transducers) 10A-10B for a consumer-electronic device. Earphones 10A-10B provide stereo sound or music to the user of the device.

The apparatus includes IC 102, earphones 10A-10B, and audio source 28. IC 102 includes capacitive sense block 252, processor 110, and control/interface circuit 26. Capacitive sense block 252 couples to earphones 10A-10B via two pairs of capacitive elements 106A-106B (one pair of capacitive elements 106A-106B for each channel of audio).

Capacitive elements 106A-106B may have the structure described above in connection with FIG. 6. Thus, each of capacitive elements 106A includes a section 106A1. Each of capacitive elements 106B includes a section 106B1, and an extended section 106B2.

Extended sections 106B2 are in physical proximity to, or are physically coupled to, attached to, or are a part of, earphones 10A-10B or the housings of earphones 10A-10B. For example, in some embodiments, extended sections 106B2 may be embedded into earphones 10A-10B. As another example, in some embodiments, extended sections 106B2 may be adhered or attached to earphones 10A-10B.

Control/interface circuit 26 communicates with audio source 28 via a signal link, and receives audio signals from audio source 28. Control/interface circuit 26 provides audio signals to earphones 10A-10B for the respective audio channel (right or left) via audio lines 18A1-18B1, respectively. Processor 110 may control the provision of audio signals to earphones 10A-10B, as desired.

Capacitive sense block 252 can sense the capacitance of each of capacitive elements 106A-106B. As described above, capacitive sense block 252 (in conjunction with processor 110, as desired) ignores or removes the common-mode capacitance (the capacitance between sections 106A1 and 106B1 in each pair of capacitive elements). By doing so, capacitive sense block 252 can sense the changes of capacitance in section 106B2 of capacitive elements 106B.

The interaction of the user with the electronic device, for example, with earphones 10A-10B, can cause changes in the capacitance(s) of section 106B2 of capacitive elements 106B. In response to those changes, processor 110 (more generally, IC 102) can take a variety of actions. By ignoring or removing the effect of the common capacitance, sensing apparatus according to the disclosed concepts can ignore when a conductive or partly conductive object, such as a hand, approaches capacitive element 106A, as desired.

For example, suppose that earphone 10A drops out of the user's ear, or that the user removes earphone 10A from his/her ear. Capacitive sense block 252 senses the change in the respective section 106B2 of capacitive element 106B corresponding to earphone 10A. Capacitive sense block 252 may report the change in capacitance to processor 110. In response, processor 110 may take a desired or predetermined action.

In one exemplary embodiment, in response to the reported change in capacitance, processor 110 may cause control/interface circuit 26 to interrupt the provision of the audio signal to earphone 10A. In another exemplary embodiment, in response to the reported change in capacitance, processor 110 may turn off an audio amplifier or circuit that would provide the audio signal to earphone 10A during normal operation, thus saving power. In yet another exemplary embodiment, in response to the reported change in capacitance, processor 110 may cause the mixing of the two audio channels and providing the resulting signal to earphone 10B (given that the user only has earphone 10B in his/her ear).

As persons of ordinary skill in the art who have the benefit of the description of the disclosed concepts understand, the circuit shown in FIG. 7 may provide other functionality, as desired. For example, suppose that the user removes both earphones 10A-10B from his/her ears. In one exemplary embodiment, in response to the reported changes in capacitance, processor 110 may cause control/interface circuit 26 to interrupt the provision of the audio signal to earphones 10A-10B. In another exemplary embodiment, in response to the reported changes in capacitance, processor 110 may turn off the audio amplifiers or circuits that would provide audio signals to earphone 10A-10B during normal operation, thus saving power. In yet another exemplary embodiment, in response to the reported changes in capacitance, processor 110 may cause the routing of the audio signals to loudspeakers (not shown in FIG. 7), rather than to earphones 10A-10B.

Note that, as persons of ordinary skill in the art who have the benefit of the description of the disclosed concepts understand, one may make a variety of modifications to the embodiment shown in FIG. 7 to provide other or different functionality, as desired. For example, rather than stereo audio, one may use one earphone and one pair of capacitive elements 106A-106B to provide mono audio.

As another example, one may include a microphone to provide a headset. In such an embodiment, in response to the removal of one or both earphones 10A-10B from the user's ear(s), processor 110 may cause the muting of the microphone, or shutting down or disabling audio circuitry to save power. As yet another example, one may combine the functionality of processor 110 and control/interface 26. In another example, one may use another processor to implement the functionality of control/interface circuit 26.

Another application of the remote capacitive sensing according to the disclosed concepts relates to common-mode wires or common-mode sensors. The inclusion of the common-mode wires allows the mitigation or sensing (and taking appropriate actions in response to) interference.

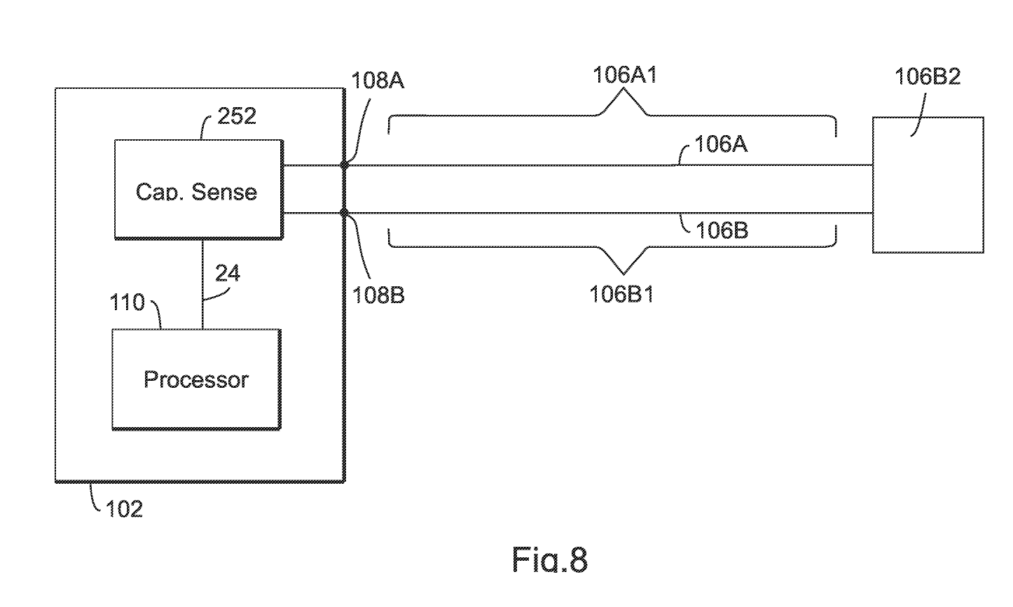

FIG. 8 shows a simplified block diagram of a capacitive sensing apparatus that includes a common-mode wire according to an exemplary embodiment. The embodiment in FIG. 8 includes IC 102 and capacitive element 106A. Similar to the embodiment of FIG. 6, the apparatus also includes capacitive element 106B, which has section 106B1 and extended section 106B2. Extended section 106B2 may constitute a sensor, as desired.

Capacitive element 106A serves as a common-mode wire. Suppose that interference impinges sections 106A1 and 106B1 of capacitive elements 106A-106B. The interference causes “common-mode capacitance” at the input of capacitive sense block 252. As noted above, capacitive sense block 252 ignores the common-mode capacitance. As a result, capacitive sense block 252 responds to the desired changes in capacitance in section 106B2 of capacitive element 106B, rather than capacitance changes in sections 106A1-106B1 as a result of the interference. In other words, the apparatus shown in FIG. 8 reduces or eliminates the impact of interference along the connection path between IC 102 and extended section 106B2 (or generally, a sensor).

One may use the common-mode-wire apparatus described above in a wide variety of applications, as persons of ordinary skill in the art who have the benefit of the description of the disclosed concepts understand. Examples include medical instrumentation, industrial applications, and the like, where one might wish to detect signals and/or changes in capacitance in the presence of interference.

Remote capacitive sensing apparatus according to the disclosed embodiments can also provide protection of the sensing and processing electronic circuit (e.g., IC 102) from sources of heat, radiation, or other elements that might damage or adversely affect such circuitry or semiconductors. One example relates to cooking apparatus.

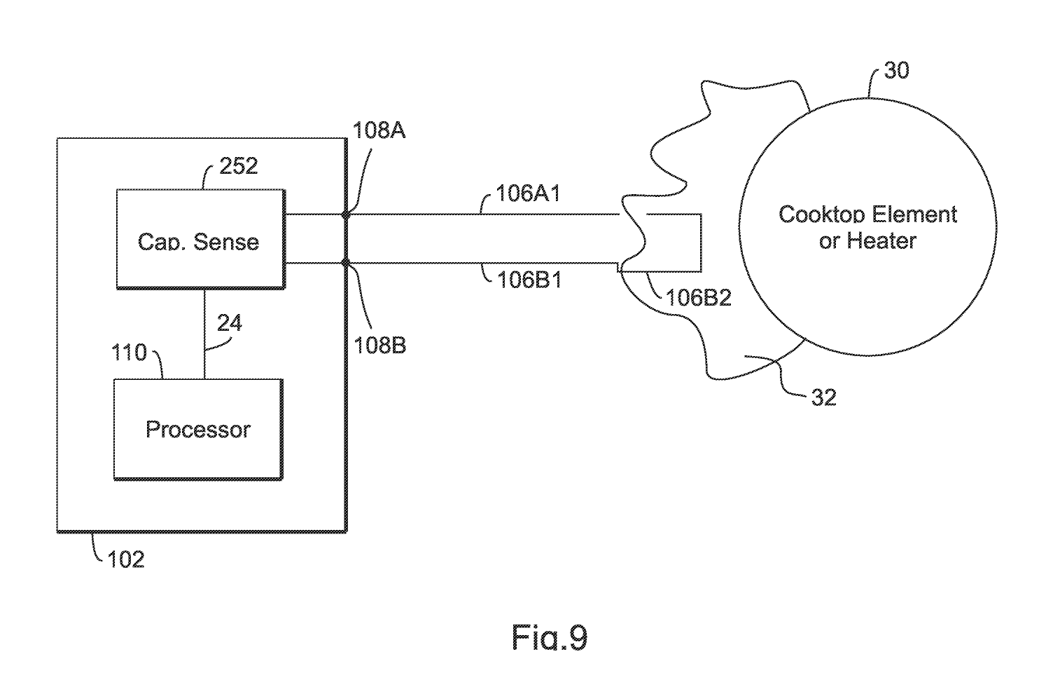

FIG. 9 shows simplified block diagram of a capacitive sensing apparatus, used in a cook-top application, according to an exemplary embodiment. The apparatus includes a capacitive sensor for detecting the condition of a cook-top element or heating element or heater 30.

Referring to FIG. 9, the apparatus includes IC 102 coupled to capacitive elements 106A-106B, as described above. To avoid damage to IC 102 from heat, one may physically place IC 102 a safe distance from cook-top element 30.

Extended section 106B2 of capacitive element 106B allows remote monitoring of cook-top element 30 and events related to its operation. In other words, as detailed above, the capacitive sensing apparatus ignores the common-mode capacitance, and reacts mainly or substantially to changes of capacitance in section 106B2 of capacitive element 106B.

For example, suppose that one removes a pot from cook-top element 30, but fails to turn off power or fuel to it. The apparatus shown in FIG. 9 senses the change of capacitance as a result of the removal of the pot. If the user does not turn off the source of power or fuel to cook-top element 30, the apparatus can either do so automatically and/or or provide an alarm, either instantly, or after a desired, programmable, or preset delay.

As another example, suppose that a pot placed on cook-top element 30 boils over, resulting in spill 32. Spill 32 causes a change of capacitance in section 106B2 of capacitive element 106B, which IC 102 senses. The capacitive sensing apparatus can then take appropriate action, such as lower the heat provided to the pot, remove the source of power or fuel, provide an alarm to the user, etc., as desired.

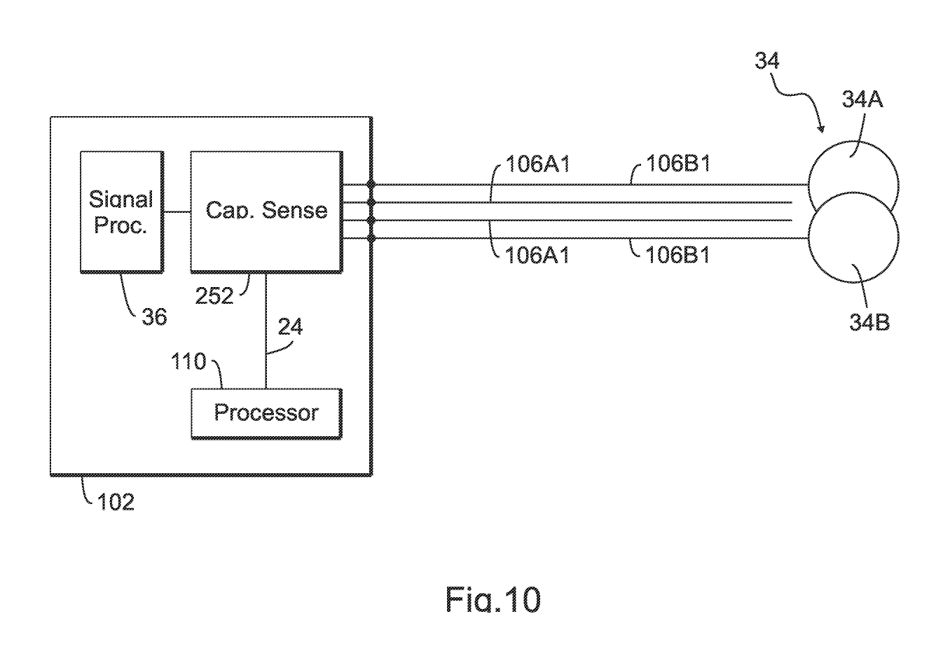

In yet another application, one may use remote sensing of capacitance in test or measurement instrumentation or devices. FIG. 10 depicts a simplified block diagram of a capacitive sensing apparatus according to an exemplary embodiment for use in test or measurement applications.

Specifically, the apparatus in FIG. 10 includes an IC 102 coupled to capacitive sensor 34 via two pairs of capacitive elements. Each pair of capacitive elements includes capacitive elements 106A-106B. Sensor 34 includes plates 34A-34B. Thus, together, plates 34A-34B form a capacitor. The capacitance of the capacitor formed by plates 34A-34B of sensor 34 may change in response to a quantity that one wishes to measure, test, or monitor, for example, humidity, strain, pressure, proximity, etc. Put another way, by sensing or measuring the capacitance or changes in capacitance of in sensor 34, one may test, measure, or monitor the desired quantity.

One pair of capacitive elements 106A-106B couples to plate 34A of sensor 34. The second pair of capacitive elements 106A-106B couples to plate 34B of sensor 34. By using the capacitive elements 106A-106B, one may physically place IC 102 a relatively long distance from sensor 34. Doing so allows protecting IC 102 from the elements, such as moisture, heat, wind, sunshine, or other undesired or damaging elements, while allowing the remote sensing of changes of capacitance in sensor 34.

As persons of ordinary skill in the art who have the benefit of the description of the disclosed concepts understand, one may make a variety of modifications to the apparatus of FIG. 10, as desired. For example, rather than using a pair of plates 34A-34B, one may use a single plate, say, plate 34A, and measure the change of capacitance between that plate and a ground plane or earth ground or a ground terminal. As another example, one may use a pair of plates 34A-34B, as shown, but configure IC 102 to perform differential measurements of the capacitance of plates 34A-34B with respect to a ground plane or earth ground or a ground terminal. As yet another example, one may use one capacitive element or section 106A1 (i.e., a common capacitive element or section 106A1), rather than two, as desired.

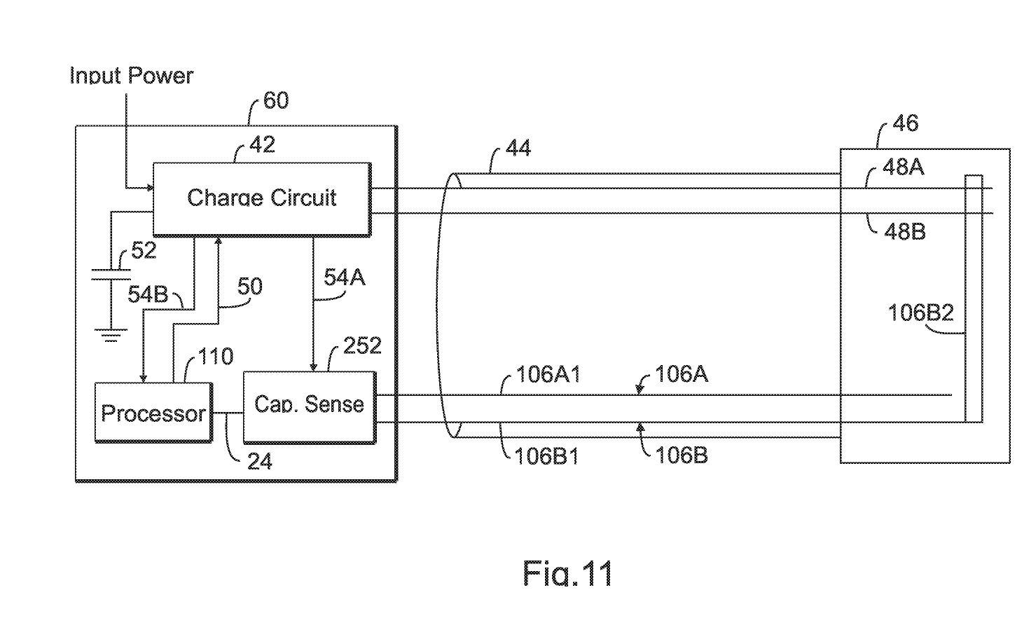

In yet another application, one may use remote sensing of capacitance in smart electronic devices or appliances, for example, chargers. FIG. 11 shows a simplified block diagram of a charger according to an exemplary embodiment, which includes capacitive sensing circuitry.

The charger includes charge/sensing circuit 60, connector 46, and capacitive elements 106A-106B. Charge/sensing circuit 60 couples to connector 46 via conductors 48A-48B and sections 106A1-106B1 of capacitive elements 106A-106B. Capacitive element 106B includes an extended section 106B2.

Extended section 106B2 is in physical proximity to, or are physically coupled to, attached to, or is a part of, connector 46 or the housing of connector 46. For example, in some embodiments, extended section 106B2 may be embedded into connector 46. As another example, in some embodiments, extended section 106B2 may be adhered or attached to in connector 46.

Connector 46 may have a variety of configurations, as persons of ordinary skill in the art who have the benefit of the description of the disclosed concepts understand. For example, in some embodiments, connector 46 may constitute a universal serial bus (USB) connector. In some embodiments, the set of conductors (conductors 48A-48B and sections 106A1-106B1 of capacitive elements 106A-106B) may constitute a cable 44.

Charge/sensing circuit includes charge circuit 42. Charge circuit 42 receives input power, and converts the input power to an output voltage or current suitable for charging the intended or desired device. Charge circuit 42 provides the charging voltage or current to the device via conductors 48A-48B.

Charge/sensing circuit 60 also includes capacitive sense block 252, processor 110, and capacitor 52. Charge circuit 42 provides a charging current to capacitor 52. Capacitor 52 provides power to cap sense block 252 and processor 110.

Using capacitive elements 106A-106B, capacitive sense block 252, and processor 110, charge/control circuit 60 can determine whether a load (device to be charged) is coupled or connected to connector 46. If so, and when connected to the mains or input power, charge/control circuit 60 provides charging voltage or current to the intended load via connector 46. If, however, a load is not coupled or connected to connector 46, capacitive sense block 252 and processor 110 sense this condition. Processor 110 can use a link or line 50 to disable or shut down charge circuit 42 in order to reduce power consumption or waste of power in charge/control circuit 60.

If charge/control circuit 60 loses the input power (e.g., loss of mains power, or the user unplugs the charger from the mains), the charger ceases to charge the attached device. Using the charge stored on capacitor 52, charge/control circuit 60 can continue to monitor for a period of time whether the load (device to be charged) is coupled or connected to connector 46. During that period of time, if the input power is restored, charge/control circuit 60 senses this condition, and resumes charging the load connected or coupled to connector 46.

The length of the period of time during which charge/control circuit 60 can continue to monitor whether the load (device to be charged) is coupled or connected to connector 46 depends on a number of factors. Such factors include the capacitance of capacitor 52, and the amount of power that capacitive sense block 252 and processor 110 consume. To extend the period of time, one may employ one or more approaches. First, one may use circuitry with relatively low power-consumption to implement capacitive sense block 252 and processor 110, as persons of ordinary skill in the art who have the benefit of the description of the disclosed concepts understand. Second, one may conduct periodic checks to determine whether the load (device to be charged) is coupled or connected to connector 46.

As noted, one aspect of the disclosed concepts relates to apparatus for measuring or sensing capacitance or changes in capacitance (e.g., capacitance of capacitive elements or changes in capacitance of capacitive elements). As persons of ordinary skill with the benefit of the disclosed concepts understand, one may measure capacitance in exemplary embodiments in a wide variety of ways, as desired, depending on factors such as specifications for a given application, etc. The following description provides details of measuring capacitance according to some exemplary embodiments.

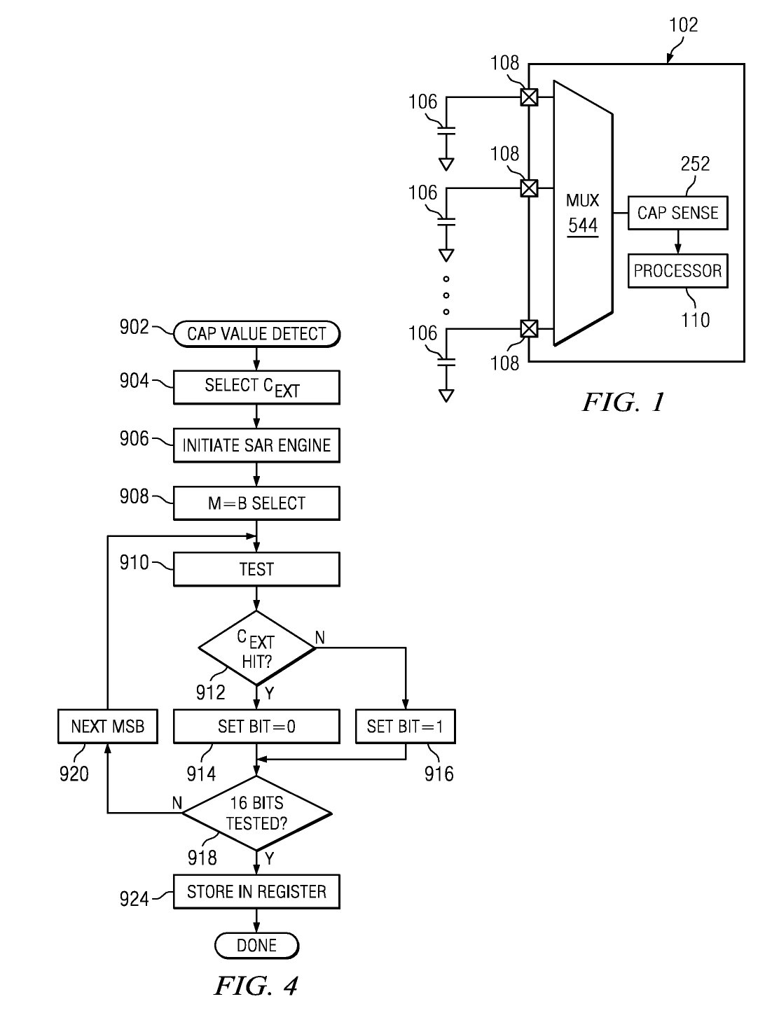

Referring now to FIG. 1, there is illustrated an overall block diagram of an IC 102 that interfaces with a plurality of capacitive elements, for example, capacitor touch pads, 106 that are each interfaced with the IC 102 through respective external pins 108. Each of the capacitor touch pads 106 is comprised of any type of external capacitor wherein the capacitance thereof can be varied by, for example, touching the capacitor with a finger or placing the finger in close proximity thereto so as to affect the capacitance value thereof. It should also be understood that any type of capacitive element could be used and not just a capacitive touch pad. The capacitor touch pads 106 can be stand alone elements or they can be part of a capacitive sensor array.

In some embodiments, a single capacitor 106 couples to capacitive sense block or circuit 252 (i.e., without multiplexer (MUX) 544). In some embodiments, IC 102 includes a MUX 544 which is operable to select one of the external pins 108 and one plate of an associated capacitor touch pad 106 for input to a capacitive sense block 252. The capacitive sense block 252 is operable to determine the value of the capacitance associated with the selected pin 108 (or with one or more pins 108, generally). This will then allow a determination to be made as to the value of the capacitance associated with pin 108, which will be referred to as the capacitance associated with an “external capacitance switch,” this value being the sum of the value of the associated capacitor touch pad 106 and any parasitic capacitance, this parasitic capacitance the result of a finger touch, external interference, etc. As persons of ordinary skill in the art with the benefit of the disclosed concepts understand, however, the term “external capacitance switch” does not limit the utility and application of the disclosed concepts. Generally, one may use the disclosed circuitry and techniques to sense the value of one or more capacitors 106. For example, in some embodiments, one may sense a varying value of a capacitor 106. As an another example, in some embodiments, one may sense the value of one or more capacitors 106 and compare those values to preset, predetermined, or threshold values, as desired.

In some embodiments, the information as to the capacitance value of the external capacitance switch is then passed on to a processor 110 for the purpose of determining changes in capacitance value, etc. with the use of appropriate techniques. One example of an application of such is described in U.S. patent application Ser. No. 12/146,349, filed on Jun. 25, 2008, entitled “LCD CONTROLLER CHIP,” which is incorporated herein by reference in its entirety. It should be understood that the multiplexer 544 could be realized with a switch.

In general, one application would be to individually sense the static value of each of the external capacitance switches are each of the pins 108 at any given time and continually scan these external capacitance switches to determine if a change in capacitance has occurred, i.e., the value of the capacitance value has changed by more than a certain delta. If so, with the use of a proprietary algorithm, a decision can be made as to whether this constitutes a finger touch or external interference. However, the capacitive sense block 252 is primarily operable to determine the value of the external capacitance switch (or capacitors, generally) and then, possibly, provide some hardware control for accumulating the particular values and comparing them with prior values for generating an interrupt to the processor 110. However, the first object of the capacitive sense block 252 is to determine the value of the external capacitance switch connected to a particular pin 108 being scanned at any particular time.

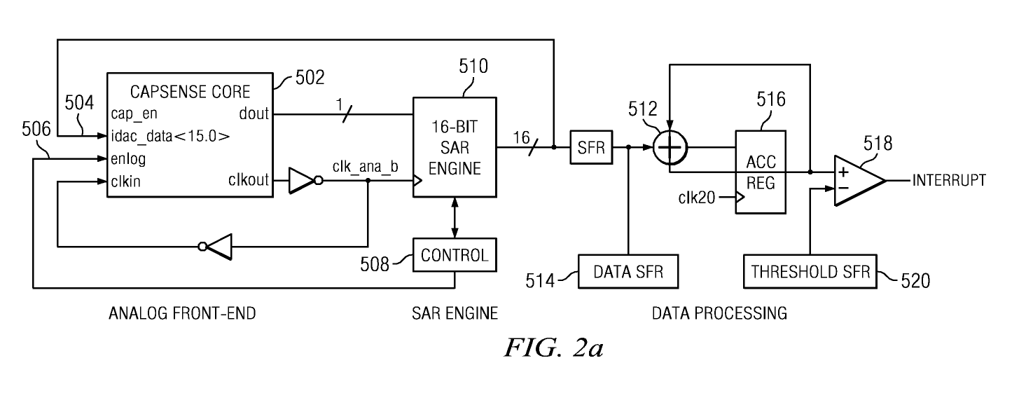

Referring now to FIGS. 2a and 2b, there is illustrated a functional block diagram of the capacitive touch sense block 252. The analog front end circuitry 502 shown in FIG. 2a is responsible for a connected external capacitance switch for the purpose of determining the value of the capacitance. The analog front end circuitry 502 receives a 16-bit current control value which is provided to the input IDAC_DATA via input 504 for controlling a variable current source. This current is generated by a current digital-to-analog converter (IDAC), not shown. The analog front end also receives an enable signal at the input ENLOG 506 from a control circuit 508. The analog front end circuitry 502 additionally provides a clock signal. A 16-bit successive approximation register engine 510 controls a first variable current source within the analog front end circuitry 502 that drives the external capacitance switch. The 16-bit SAR engine 510 changes a control value which defines a present value of a variable current I_{A} that drives an external capacitor C_{EXT} (as seen in FIG. 2b) on a selected one of the output pads 541. This selection is made by multiplexer 544, and the capacitor C_{EXT} corresponds to capacitor touch pad 106 in combination with any parasitic capacitance the external capacitance switch. The current source generating the current I_{A} that drives the selected external capacitor C_{EXT} from current source 546 will cause a voltage to be generated on that external capacitance switch C_{EXT} that is compared to the voltage across an internal reference capacitor C_{REF} (as shown in FIG. 2b). This capacitor C_{REF} if an internal capacitor and the current provided thereto from an internal current source is a constant current. Both capacitors, the selected capacitor C_{EXT} and the reference capacitor C_{REF}, are initialized at a predetermined point and the currents driven thereto allow the voltages on the capacitors C_{EXT} and C_{REF} to ramp-up at the rate determined by the respective capacitance value and the current provided by the respective current sources that provide driving current thereto. By comparing the ramp voltages and the ramp rates, a relative value of the two currents can be determined. This is facilitated by setting a digital value to the IDAC and determining if the ramp rates are substantially equal. If the capacitors C_{EXT} and C_{REF} were identical, then the two ramp rates would be substantially identical when the current driving capacitors C_{EXT} and C_{REF} are substantially identical. If the capacitor C_{EXT} is larger, this would require more current to derive a ramp rate that is substantially identical to the capacitor C_{REF}. This will be described in more detail herein below. Once the SAR algorithm is complete, the 16-bit value “represents” the capacitance value of the external capacitance switch on the external node.

The current source control value for variable current source 546 is also provided to an adder block 512. The control value establishing the necessary controlled current is stored within a data Special Function Register (SFR) 514 representing the capacitive value of the external capacitive switch. This SFR 514 is a register that allows for a data interface to the processor 110. Second, an input may be provided to an accumulation register 516 for the purpose of determining that a touch has been sensed on the presently monitored external capacitance switch of the capacitive sensor array. Multiple accumulations are used to confirm a touch of the switch, depending upon the particular algorithm utilized. The output of the accumulation register 516 is applied to the positive input of a comparator 518 which compares the provided value with a value from a threshold SFR register 520. When a selected number of repeated detections of activations, i.e., changes, of the associated external capacitance switch within the capacitive sensor array have been detected, the comparator 518 generates an interrupt to the processor 110. The output of the accumulation register 516 is also provided to the adder block 512.

Referring now specifically to FIG. 2b, there is illustrated a more detailed diagram of the analog front end circuitry 502. The analog front end circuitry 502 includes control logic 530 that provides an output dₒᵤₜ that is provided to the successive approximation register engine 510 and the output clock “clk_out.” dₒᵤₜ indicates a condition indicating that the ramp voltage on C_{EXT} was faster than the ramp voltage across C_{REF}, this indicating that the SAR bit being tested needs to be reset to “zero.” The logic 530 receives an input clock signal “clkn” and provides an output clock signal “clk” and an output clock signal “clkb” (clock bar) to a series of transistors.

The output “clk” is provided to a first n-channel transistor 532. The drain/source path of transistor 532 is connected between node 534 and ground. The gate of transistor 532 is connected to receive the “clk” signal. The gates of transistors 536 and 538 are connected to the clock bar signal “clkb.” The drain/source path of transistor 536 is connected between node 540 and ground, node 540 being connected to an output pad 541 via multiplexer 544. The drain/source path of transistor 538 is connected between node 542 and ground.

The transistors 536, 538 and 532 act as discharge switches for capacitors C_{EXT}, C_{REF} and C_{P2}, respectively. Capacitor C_{EXT} is connected between the associated output of multiplexer 544 and ground. Capacitor C_{REF} is connected between internal node 542 and ground. Capacitor C_{P2} is connected between internal node 534 and ground. The capacitor C_{EXT} represents the external capacitance switch for the selected capacitor touch pad 106 of the capacitive sensor array and is variable in value. The capacitive value thereof can change based upon whether the associated capacitor touch pad 106 is being actuated by the finger of the user or not. The multiplexer 544 or other switching circuitry is utilized to connect other external capacitance switches within the capacitive sensor array to node 540 to determine their capacitive values.

The variable current source 546 provides a current input to node 540. The variable current source 546 (an IDAC) is under the control of a 16-bit data control value that is provided from the successive approximation register engine 510. The current source 546 is used for charging the capacitor C_{EXT} when transistor 536 is off, this providing a “ramp” voltage since current source 546 provides a constant current I_{A}. When transistor 536 is conducting, the charging current and the voltage on capacitor C_{EXT} are shorted to ground, thus discharging C_{EXT}.

The current source 548 provides a constant charging current I_{B} into node 542. This charging current provides a charging source for capacitor C_{REF} when transistor 538 is off to generate a “ramp” voltage, and the current I_{B} is sinked to ground when transistor 538 is conducting, thus discharging capacitor C_{REF}. Likewise, current source 550 provides a constant charging current I_{C} to node 534. This current source 550 is used for charging capacitor C_{P2} to generate a “ramp” voltage when transistor 532 is off, and I_{C} is sinked to ground when transistor 532 is conducting, thus discharging capacitor C_{P2}.

Connected to node 540 is a low pass filter 552. The low pass filter 552 is used for filtering out high frequency interference created at the external capacitance switch in the capacitive sensor array. The output of the low pass filter 552 is connected to the input of a comparator 554. The comparator 554 compares the ramp voltage at node 540 representing the charging voltage on capacitor C_{EXT} to a threshold reference voltage V_{REF} (not shown) and generates a negative pulse when the ramp voltage at node 540 crosses the reference voltage V_{REF}. This is provided to the control logic 530 as signal “doutb.” Similarly, a comparator 556 compares the ramp voltage of the fixed capacitance C_{REF} at node 542 with the threshold reference voltage V_{REF} and generates an output negative pulse “refb” when the voltage at node 542 crosses the threshold reference voltage V_{REF}. Finally, the comparator 558 compares the ramp voltage at node 534 comprising the charge voltage on capacitor C_{P2} with the threshold reference voltage V_{REF} and generates an output responsive thereto as signal “p2b” when the ramp voltage at node 534 exceeds the threshold reference voltage.

The circuit in FIG. 2b operates by initially resetting the voltage on capacitors C_{EXT} and C_{REF} to zero by turning on transistors 536 and 538. This causes the voltage on capacitors C_{EXT} and C_{REF} to discharge to ground. The transistors 536 and 538 are then turned off, and the voltage on capacitors C_{EXT} and C_{REF} begins to ramp up toward the reference voltage V_{REF} responsive to the current output of the respective current sources 546 and 548. If the voltage across capacitor C_{EXT} reaches the threshold voltage V_{REF} prior to the voltage across capacitor C_{REF} reaching the threshold voltage, this trips the output of comparator 554 to provide a negative pulse and this information is provided from the control logic 530 as output dₒᵤₜ to the successive approximation register engine 510 to allow the SAR bit being tested to remain a “one”, and a next value of the 16-bit control value for the current source 546 will be selected for testing when CREF crosses the threshold reference voltage level V_{REF}. Since the comparator 554 “tripped” before comparator 556, this indicates less current is needed for the next bit tested.

The control logic 530 generates the dₒᵤₜ signal controlling the operation of setting bits of the 16-bit SAR control value by the successive approximation register engine 510 responsive to the output from comparator 554. The successive approximation register engine 510 initially sets a most significant bit of the 16-bit control value to “one” and the rest to “zero” to control the variable current source 546 to operate at one-half value. If the output of comparator 554 goes low prior to the output of comparator 556 going low, the dₒᵤₜ signal provides an indication to the successive approximation register engine 510 to reset this bit to “zero” and set the next most significant bit to “one” for a next test of the 16-bit SAR control value. However, when the output of comparator 556 goes low prior to the output of comparator 554 going low, the bit being tested remains set to “one” and a next most significant bit is then tested. This process continues through each of the 16-bits of the 16-bit control value by the successive approximation register 510 engine responsive to the signal dₒᵤₜ from the control logic 530 until the final value of the 16-bit control value to the variable current source 546 is determined.

The “clkb” output resets the voltages across C_{EXT} and C_{REF} by turning on transistors 536 and 538 to discharge the voltages on these capacitors, and the transistors 536 and 538 are turned off to enable recharging of capacitors C_{EXT} and C_{REF} using the provided respective variable current and the respective reference current, respectively. The voltages across the capacitors C_{EXT} and C_{REF} are again compared by comparators 554 and 556 to the threshold reference voltage V_{REF}. When the output of comparator 556 provides a negative output pulse prior to the output of comparator 554 this provides an indication to set an associated bit in the 16-bit control value to “one” as described above. The 16-bit control value that is being provided to the variable current source 546 will be stored when the SAR algorithm is complete at which point both voltages ramp-up at substantially the same rate. The current I_{A} being provided by the variable current source 546 that is associated with the established 16-bit value, the fixed current I_{B} of current source 548 and the fixed capacitance value C_{REF} may be used to determine the value of the capacitance C_{EXT} according to the equation I_{A}/I_{B}×C_{REF} using associated processing circuitry of the array controller. Even though the actual value of C_{EXT} could be determined with this equation, this is not necessary in order to determine that the value of the external capacitance switch has changed. For capacitive touch sensing, one should determine a “delta” between a prior known value of the external capacitance switch and a current value thereof. Thus, by repeatedly scanning all of the external capacitance switches in the capacitive sensor array and comparing a current value therefor with the prior value therefor, a determination can be made as to whether there is a change. Thus, one uses a “normalized” value stored and then compares this pre-stored normalized value with a new normalized value. The delta value, rather than the actual value, determines whether a change exists or has occurred.

By using similar circuitry to generate the ramp voltages and to compare the voltages at nodes 540 and 542, substantially all common mode errors within the circuitry are rejected. Filter 552 upsets the common mode balance between the circuits in order to prevent high frequency interference from outside sources such as cell phones. The circuitry for measuring the voltages at the nodes provides a proportional balance between the internal reference voltage and the external capacitance voltage. Thus, errors within the comparators or the reference voltage V_{REF} are not critical as they are the same in each circuit.

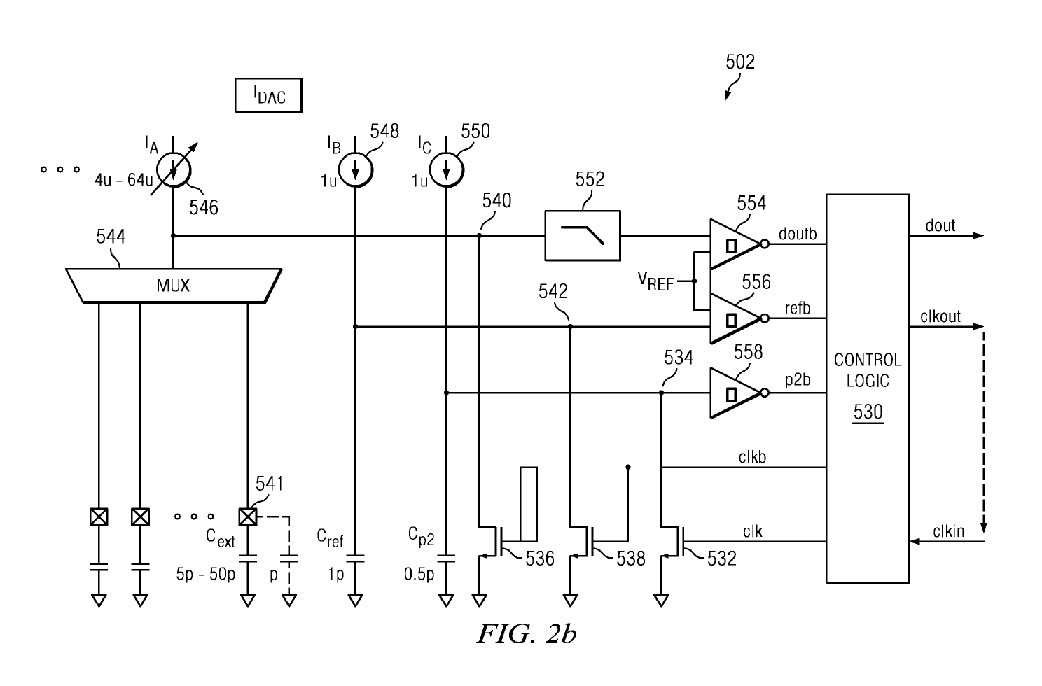

Referring now to FIG. 3, there is illustrated a timing diagram describing the operation of the analog front end circuitry 502 of FIG. 2b. Nothing may occur within the analog front end circuitry 502 until the enable signal goes logically “high” at time T₁. Responsive to the enable signal going high at time T₁ the “clk” signal goes low. Shortly after time T₁, the voltage CP2 on capacitor C_{P2} begins ramping up at point 670. (Note that the ramp rate for the initial ramp is slower until a point 671 due to start up delays.) When the voltage reaches a set reference voltage level at time T₂, the end of a first phase of a two phase clock the comparator 558 generates a low clock pulse as the second phase of the two phase clock as signal P2B and the CLK signal (and CLKOUT signal) goes high. This provides the clock for the analog front end circuitry 502. The CLKB (clock bar) signal also goes low at the same time. The CLKB signal going low turns off transistors 536 and 538 causing the respective voltages across C_{EXT} and C_{REF} to begin ramping up. Once one of voltages CREF or CEXT reaches a reference voltage V_{REF} (in this case the voltage CREF reaches the threshold voltage V_{REF} first at time T₃) the output of comparator 556 generates a low pulse as signal REFB. This causes the CLKOUT and CLK signals to go low and the CLKB signal to go high. When the CLKB signal goes high, transistors 536 and 538 are turned on causing the voltages CREF and CEXT to be discharged. Turning off transistor 532 by CLK going low at T₃ causes a voltage CP2 to begin ramping up on capacitor C_{P2}. This voltage continues to ramp up until it reaches a reference voltage at time T₄ causing the output of comparator 558 P2B to pulse low. This causes clock signal CLK and CLKOUT to go high and clock signal CLKB to go low. This discharges the voltage on capacitor C_{P2} and begins ramping up the voltages on capacitors C_{EXT} and C_{REF}.

At time T₅, the voltage CEXT on capacitor C_{EXT} reaches the reference voltage prior to the voltage CREF reaching the reference voltage. This causes comparator 554 output to go low generation dₒᵤₜ. When the voltage CREF reaches the reference voltage at time T₆, a low pulse is generated on REFB, and the CLKOUT signal and CLK signal go low while the CLKB signal goes high. This discharges the voltage CREF and CEXT and begins charging of capacitor C_{P2} with voltage CP2. The process repeats as necessary for each of the 16-bits of the SAR algorithm.

With further reference to the timing diagram of FIG. 3 and the diagrams of FIGS. 2a and 2b, the operation will be described in more detail. As noted herein above, the basic clock is provided by CP2 and CREF. CP2 provides one phase of the clock, i.e., that portion when the clock is low and CREF provides the second phase of the clock, i.e., that portion when the clock is high. Therefore, CREF controls the second phase and CEXT does not. With reference to the two ramp voltages for CREF and CEXT, this basically represents a race to the threshold voltage. It is noted that both of the comparators 554 and 556 are fabricated with the same circuitry on the same chip and, therefore, drifts with temperature, delays, etc. will be substantially identical such that any variations thereof will be rejected on a common mode basis. The reference voltage, V_{REF}, for both comparators 554 and 556 should be substantially identical and comparator delays be substantially identical (for example, in each case, a few percent, say, less than 1% or less than 5% or less than 10%). Further, to provide additional immunity from high frequency noise, over and above that associated with the filter 552, these comparators 554 and 556 are designed to be somewhat “sluggish,” and such can be accommodated in the SAR algorithm. This provides additional noise immunity. In order to have low frequency noise immunity, the low frequency noise should ride on the ramp voltage but the ramp voltage be reset after each bit of the 16-bit SAR cycle is tested such that the low frequency noise is present mainly or entirely over one cycle of the 1 kHz SAR cycle. This means that the low frequency noise constitutes a factor for a period of one microsecond. This provides low frequency noise rejection.

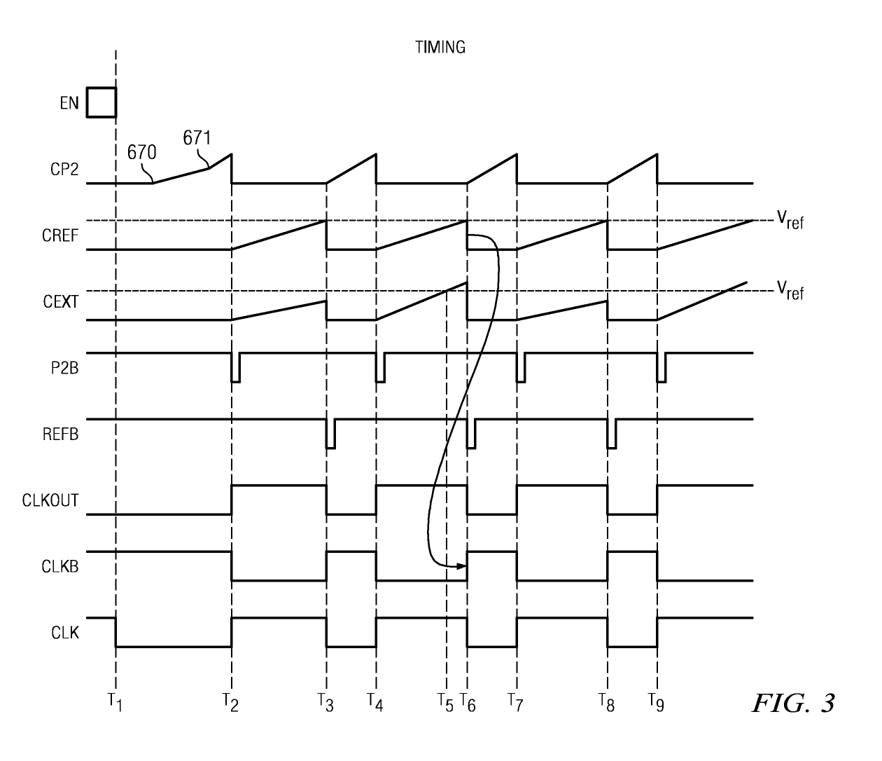

Referring now to FIG. 4, there is illustrated a flow chart depicting the operation of the SAR engine 510 which will be described in conjunction with the operation of the timing diagram of FIG. 3. The program is initiated at a block 902 and then proceeds to a function block 904. At function block 904, the multiplexer 544 is operable to select one of the pins. Note that with respect to FIG. 2b, each external capacitance switch is connected to a separate input of the multiplexer 544. It is noted that each external capacitance switch has associated therewith a 16-bit register for storing the value of that external capacitance switch after determination thereof.

Once initiated, the program flows to a block 906 to initiate the SAR engine. The first step is to select the MSB, as indicated by a block 908. This essentially positions the current source 546 at ½ value for the test. With reference to the timing diagram, this occurs on the rising edge of signal EN. At this point, the voltages on the capacitors C_{EXT} and C_{REF} have been discharged to ground and will ramp-up to a voltage depending on the current provided thereto from the respective current sources 546 and 548. As noted herein above, the current source 546 is provided with a current DAC such that the value thereof is a function of the 16-bit value which, for the first cycle is “1000000000000000.” The program then flows to a function block 910 which is a test of the particular bit. This test is the ramp-up of the two voltages to determine which arrives at the reference voltage first. In essence, this is a race for both of these voltages to reach the reference voltage.

Basically, for each bit tested, a determination is made as to whether more current should be provided to the capacitor C_{EXT} or less current. When, at the end of CREF, it has been determined that CEXT has crossed the threshold voltage prior to CREF crossing the threshold voltage, this is an indication that too much current has been provided, i.e., the bit being tested needs to be reset to “0.” This indicates that the current being provided by current source 546 is charging the capacitor C_{EXT} at too fast a rate. By resetting this bit to “0” and then, on the next bit tested, setting that bit to “1,” the current provided to C_{EXT} will be reduced. If, however, it were determined at the end of CREF that CEXT had not crossed the threshold voltage, it is indicated that insufficient current is being provided to the capacitor C_{EXT} and, as such, the bit being tested would remain at “1.” Note that each SAR cycle terminates at the end of CREF, at which time CLKB goes high. Therefore, it is not necessary to allow CEXT to ramp all the way up to the threshold voltage. This can be seen specifically with respect to time T₃ where the clock signal CLKB goes high at the end of CREF, i.e., there is a reset and transistors 536 and 538 are turned on to discharge C_{EXT} and C_{REF}, thus terminating the ramp-up on C_{EXT}. Thus, at the end of CREF, a particular SAR bit will be deemed as having been tested. It is at this point in time that a decision is made as to whether to leave the bit set at “1” or reset the bit at “0.” This is indicated by there being a “hit” at decision block 912 which is whether CEXT crossed the threshold before the end of CREF, indicating the time at which the voltage across C_{REF} exceeded the threshold. If CEXT exceeded the threshold prior to CREF exceeding the threshold, this would be indicated as a hit and this will indicate that too much current was supplied to C_{EXT}, i.e., current source 546 won the race to the threshold voltage. The program will flow along the “Y” path to block 914 to set the SAR bit being tested to “0” indicating that the 16-bit value should be a lower value. However, if the signal CEXT did not exceed the threshold prior to CREF exceeding the threshold, this indicates that there was not a hit, i.e., the current source 546 did not win the race, and the SAR bit being tested will be set to a “1,” as indicated by function block 916. After the SAR bit has been tested, the program will flow from either the function block 914 or 916 to decision block 918.

At decision block 918 a determination is made as to if all 16-bits have been tested and, if not, the program flows along a “N” path therefrom to a function block 920 to select the next MSB and then proceeds back to the input of block 910 to again test this bit. This will continue until all 16 bits are tested, at which time the program will flow from the decision block 918 along the “Y” path to a function block 924 to store this value in the associated register. As indicated above, this particular value represents the normalized value of the external capacitance switch. Knowing the absolute value of both currents in current sources 546 and 548 and the absolute value of the capacitor C_{REF}, it is possible to actually calculate the absolute value of the external capacitance switch. However, it is not important to calculate this value. Rather, one should have a 16-bit value for later determination as to whether the value of that external capacitance switch has changed. If the value has changed, a comparison will be made with the pre-stored 16-bit value in the register to determine if the contents need to be updated and such will happen upon such a change. This change will be noted to a program which will run an algorithm to determine if a “touch” is declared. Any type of algorithm could be utilized for this purpose. The primary purpose of the SAR engine 510 is to determine a 16-bit value for that external capacitance switch for use by the algorithm. This value then can be utilized for comparison with a previously stored value, etc., for determining if the change in capacitance value is of such a nature to declare that a touch has occurred.

It will be appreciated by those skilled in the art and having the benefit of this disclosure that this capacitive sense circuit provides a flexible solution to provide capacitive sensing capabilities for a capacitive sensor array on a single integrated chip to allow for measurement of a capacitor for the purpose of monitoring that value to determine if there has been a change. It should be understood that the drawings and detailed description herein are to be regarded in an illustrative rather than a restrictive manner, and are not intended to be limiting to the particular forms and examples disclosed. On the contrary, included are any further modifications, changes, rearrangements, substitutions, alternatives, design choices, and embodiments apparent to those of ordinary skill in the art, without departing from the spirit and scope hereof, as defined by the following claims. Thus, it is intended that the following claims be interpreted to embrace all such further modifications, changes, rearrangements, substitutions, alternatives, design choices, and embodiments.

Referring to the figures, persons of ordinary skill in the art will note that the various blocks shown might depict mainly the conceptual functions and signal flow. The actual circuit implementation might or might not contain separately identifiable hardware for the various functional blocks and might or might not use the particular circuitry shown. For example, one may combine the functionality of various blocks into one circuit block, as desired. Furthermore, one may realize the functionality of a single block in several circuit blocks, as desired. The choice of circuit implementation depends on various factors, such as particular design and performance specifications for a given implementation, as persons of ordinary skill in the art who have the benefit of the description of this disclosure understand. Other modifications and alternative embodiments in addition to those described here will be apparent to persons of ordinary skill in the art who have the benefit of this disclosure. Accordingly, this description teaches those skilled in the art the manner of carrying out the disclosed concepts and are to be construed as illustrative only.

The forms and embodiments shown and described should be taken as illustrative embodiments. Persons skilled in the art may make various changes in the shape, size and arrangement of parts without departing from the scope of the disclosed concepts in this document. For example, persons skilled in the art may substitute equivalent elements for the elements illustrated and described here. Moreover, persons skilled in the art who have the benefit of this disclosure may use certain features of the disclosed concepts independently of the use of other features, without departing from the scope of the disclosed concepts.

1. An apparatus, comprising:
an integrated circuit (IC), configured to sense capacitance;
a first capacitive element coupled to the IC, the first capacitive element having first section; and
a second capacitive coupled to the IC, the second capacitive element having first and second sections,
wherein the first section of the first capacitive element and the first section of the second capacitive element have substantially the same lengths, shapes, and/or capacitance.

2. The apparatus according to claim 1, wherein the IC comprises a capacitive sense circuit coupled to the first and second capacitive elements.

3. The apparatus according to claim 2, wherein the IC further comprises a processor coupled to the capacitive sense circuit.

4. The apparatus according to claim 1, wherein the second section of the second capacitive element extends beyond the first section of the second capacitive element.

5. The apparatus according to claim 1, wherein the IC ignores a change of capacitance of the first sections of the first and second capacitive elements.

6. The apparatus according to claim 1, wherein the IC senses a change of capacitance of the second section of the second capacitive element.

7. The apparatus according to claim 1, further comprising an audio transducer physically coupled to the second section of the second capacitive element, the audio transducer coupled to receive an audio signal from an audio source.

8. The apparatus according to claim 7, wherein, in response to a change of capacitance of the second section of the second capacitive element, the IC causes an interruption of the audio signal.

9. The apparatus according to claim 7, wherein, in response to a change of capacitance of the second section of the second capacitive element, the IC causes the audio source to be powered down.

10. The apparatus according to claim 1, further comprising a source of heat located physically in proximity of the second section of the second capacitive element.

11. The apparatus according to claim 10, wherein the source of heat comprises a cooking heat source.

12. The apparatus according to claim 11, wherein, in response to a change of capacitance of the second section of the second capacitive element, the IC causes a heat level of the cooking heat source to be reduced.

13. The apparatus according to claim 1, further comprising charge circuitry coupled detachably to a load via a connector.

14. The apparatus according to claim 13, wherein the second section of the second capacitive element is physically coupled to the connector.

15. The apparatus according to claim 14, wherein, in response to a change of capacitance of the second section of the second capacitive element, the charge circuitry provides a charge voltage or current to the load when the load is coupled to the connector and the charge circuitry is coupled to a source of input power.

16-27. (canceled)
